(19) United States
(12) Patent Application Publication
(10) Pub. No.: US 2005/0002046 A1
(43) Pub. Date: Jan. 6, 2005

(54) Method for transforming a colour image

(75) Inventors: Pieter Wilhelmus Verbeek, Nootdorp (NL); Judith Dijk, Zeist (NL)

Correspondence Address: PEACOCK MYERS AND ADAMS P C, P O BOX 26927, ALBUQUERQUE, NM, 871256927, US

(73) Assignee: Technische Universiteit Delft, Delft (NL)

(21) Appl. No.: 10/742,169

(22) Filed: Dec. 19, 2003

(30) Foreign Application Priority Data
Dec. 24, 2002 (NL) NL 1022258

(51) Int. Cl. G06F 15/00; G03F 3/08

(52) U.S. Cl. 358/1.9; 358/518; 382/167

(57) ABSTRACT

The invention relates to a method of transforming a colour image, wherein for each separate pixel a measured level of lightness, a measured chroma and a measured colour is determined, followed by a predetermined adjustment in the three-dimensional level of lightness, chroma and colour, wherein a. for each separate pixel a direction of adjustment is determined by selection of a three-dimensional adjustment level for lightness, chroma and colour change, b. and in that at the three-dimensional adjustment level selected the maximum available lightness change is determined, whereafter c. for each separate pixel the measured lightness level, the measured chroma and the measured colour is changed in the direction of the selected three-dimensional adjustment level in concurrence with a predetermined function, which at most amounts to the maximum available lightness change at the selected three-dimensional adjustment level.

The invention relates to a method for transforming a colour image.

Such a method is known and is used to adapt the image observed on a display monitor or a printer and/or copier to meet particular requirements.

Generally speaking, the colours reproduced by a monitor or printer/copier cover a limited section of the colour space, known as the gamut. In this gamut each pixel has a colour or hue, a chroma and a lightness. Said colorimetric system may be a known RGB-colorimetric system, or general XYZ-colorimetric system. However, it may also be a Lab- or Luv-colorimetric system. The invention discussed below relates to any arbitrary colorimetric system. For convenience's sake, however, the explanation given below refers to an XYZ-calorimetric system, without limiting the invention thereto. The invention may be applied with equal effect and with obvious adaptations in other colorimetric systems.

The colour images intended for image reproduction should, if the occasion arises, be subjected to an image transformation to improve, for example, contrast and/or definition. A problem with the prior art transformation of a colour image is that the original colour image is transformed into a new colour image of which some of the pixels have colours that fall outside the gamut and which, in order to be reproducible, have to be brought back inside the gamut. However, according to the prior art, this correction to the image transformation carried out does not take into account the position of the pixels in relation to each other, with respect to lightness, colour and chroma.

EP-A-0 961 488 discloses a method for transforming a colour image wherein for each separate pixel a measured level of lightness, a measured chroma and a measured colour is determined, followed by a predetermined adjustment in the three-dimensional level of lightness, chroma and colour. The adjustment of said three-dimensional levels known from this publication relates to a predetermined and invariable replacement of a given three-dimensional starting level into a three-dimensional target level of lightness, chroma and colour. The adjustment serves to make it possible to reproduce colour images available in a first system, for example, a television monitor, into a second system, for example, a hard copy of the colour image.

The object of the invention is to provide a method for transforming a colour image for reproduction in one and the same system, or for reproduction in different systems having a compatible gamut that provides colour images whose separate pixels are optimally proportioned with respect to colour, chroma and lightness level to concur with the original colour image.

To this end the method according to the invention is characterised in that:
a. for each separate pixel a direction of adjustment is determined by selection of a three-dimensional adjustment level for lightness, chroma and colour change,
b. and in that at the three-dimensional adjustment level selected the maximum available lightness change is determined, whereafter
c. for each separate pixel the measured lightness level, the measured chroma and the measured colour is changed in the direction of the selected three-dimensional adjustment level in concurrence with a predetermined function, which at most amounts to the maximum available lightness change at the selected three-dimensional adjustment level.

In this manner it is possible to ensure that an image transformation always provides a transformed colour image wherein the mutual relation of the imaging aspects of the separate pixels can be optimally maintained. This result can in particular be achieved due to the fact that the method according to the invention takes into account the reproduction possibilities of the transformed colour image as determined by the gamut referred to above.

It is generally preferred for the colour to stay constant, so as to provide a true-to-life reproduction of the original image.

In a further aspect of the method according to the invention, the same is characterised in that the three-dimensional adjustment level is chosen such that only the lightness is adjusted while the chroma and the colour remain substantially constant. In this embodiment of the method according to the invention, the colour and the chroma are maintained while the image transformation only relates to an adjustment of lightness.

The adjustment of lightness that can be realised is per definition limited to the maximum of lightness adjustment available in a black and white image; with colour reproduction this lightness adjustment amounts to a fraction thereof. Nevertheless, if such a lightness adjustment threatens to fall outside the gamut, this can be taken into account when selecting the function determining the lightness adjustment, for example, by reducing the lightness adjustment exponentially or as power function, depending on the closeness of the original pixel to the gamut limit.

A further embodiment of the method according to the invention is characterised in that the function for adjustment of the lightness level and/or the chroma and/or the colour depends on a predetermined lightness threshold value, such that when exceeding the lightness threshold value, the measured lightness level will cause an increase to occur, and when falling short of the lightness threshold value, the measured lightness level will cause a reduction to occur.

This embodiment is especially suitable to improve the definition by means of the image transformation. To this end it is, moreover, desirable for the adjustment of the lightness level to be carried out only in the vicinity of a lightness leap and in such a manner that in that vicinity the mean lightness remains substantially the same.

For the sake of completeness it may be remarked that in accordance with a main aspect of the invention, an adjustment in lightness as well as chroma and colour can be obtained by means of the function if the earlier-mentioned three-dimensional adjustment level of lightness change, chroma change, colour change are chosen aptly. If the lightness space is likely to be inadequate, it can be increased by relinquishing some chroma, or changing colour, so as to increase the available space for adjusting the lightness.

In another embodiment the method according to the invention is characterised in that the function for adjusting the lightness level and/or the chroma and/or the colour depends on the absolute value of the measured lightness such that high levels are further increased and low levels are decreased or vice versa, with the meaning of “high” and “low” being previously determined. This affords a suitable method for obtaining an overall adjustment of the lightness of the total colour image.

In yet a further embodiment, the method according to the invention is characterised in that the function for adjusting the lightness level and/or the chroma and/or the colour depends on the absolute value of the measured lightness in a section of the colour image, such that low lightness levels in the section are increased and high lightness levels in the section are decreased, and wherein the meaning of “high” and “low” is previously determined. This makes it possible to effectively level out the lightness in colour images.

To the person skilled in the art it is obvious that within the framework of the invention revealed in the above description, numerous variations in grey level image transformations are conceivable, all of which apply the essence of the invention. A decisive roll plays the choice of the function determining the adjustment of the measured lightness level and/or the level of chroma and/or the colour, depending on the direction of adjustment determined by the selected three-dimensional adjustment level of lightness change, chroma change, colour change. Within the framework of the invention there is only one precondition the function must meet, namely that the transformation in a pixel brought about by this function will never result in more than the maximum available lightness change still available in the direction of the selected three-dimensional adjustment level within the limits of the gamut.

1. A method for transforming a colour image, wherein for each separate pixel a measured level of lightness, a measured chroma and a measured colour is determined, followed by a predetermined adjustment in the three-dimensional level of lightness, chroma and colour, characterised in that
a. for each separate pixel a direction of adjustment is determined by selection of a three-dimensional adjustment level for lightness, chroma and colour change,
b. and in that at the three-dimensional adjustment level selected the maximum available lightness change is determined, whereafter
c. for each separate pixel the measured lightness level, the measured chroma and the measured colour is changed in the direction of the selected three-dimensional adjustment level in concurrence with a predetermined function, which at most amounts to the maximum available lightness change at the selected three-dimensional adjustment level.

2. A method according to claim 1, characterised in that the colour stays constant.

3. A method according to claim 1 or 2, characterised in that the three-dimensional adjustment level is chosen such that only the lightness is adjusted while the chroma and the colour remain substantially constant.

4. A method according to one of the claims 1-3, characterised in that the function for adjustment of the lightness level and/or the chroma and/or the colour depends on a predetermined lightness threshold value, such that when exceeding the lightness threshold value, the measured lightness level will cause an increase to occur, and when falling short of the lightness threshold value, the measured lightness level will cause a reduction to occur.

5. A method according to claim 4, charaterised in that the adjustment of the lightness level is carried out only in the vicinity of a lightness leap and in such a manner that in that vicinity the mean lightness remains substantially the same.

6. A method according to one of the claims 1-3, caharacterised in that the function for adjusting the lightness level and/or the chroma and/or the colour depends on the absolute value of the measured lightness such that high levels are further increased and low levels are decreased or vice versa, with the meaning of “high” and “low” being previously determined.

7. A method according to one of the claims 1-3, characterised in that the function for adjusting the lightness level and/or the chroma and/or the colour depends on the absolute value of the measured lightness in a section of the colour image, such that low lightness levels in the section are increased and high lightness levels in the section are decreased, and wherein the meaning of “high” and “low” is previously determined.

8. A method according to the content of one of the preceding claims, characterised by the essence of the invention revealed in the above description and/or the files.
